(19) United States
(12) Patent Application Publication
(10) Pub. No.: US 2002/0105057 A1
(43) Pub. Date: Aug. 8, 2002

(54) Wafer surface that facilitates particle removal

(76) Inventors: Michael A. Vyvoda, Fremont, CA (US); James M. Cleeves, Redwood City, CA (US); Samuel V. Dunton, San Jose, CA (US)

Correspondence Address: KENNETH E. HORTON, RADER, FISHMAN & GRAUER PLLC, RIVERPARK CORPORATE CENTER ONE, 10653 SOUTH RIVERFRONT PARKWAY, SUITE 150, SOUTH JORDAN, UT, 84095, US

(21) Appl. No.: 09/776,009

(22) Filed: Feb. 2, 2001

(51) Int. Cl. H01L 29/06; B44C 3/12; H01L 21/20

(52) U.S. Cl. 257/618; 428/67; 438/507

(57) ABSTRACT

Wafer surfaces of the present invention comprise semiconductor and dielectric regions formed in such a way that allows the wafer surface to wet so that residual particles can be removed therefrom during a wet clean. The wafer surface comprises exposed regions of dielectric and semiconductor after a CMP removal process. The percentage of the total wafer surface area that is semiconductor after CMP is less than or equal to than a predetermined fraction, and the remainder of the wafer surface area comprises dielectric. Also, the regions of semiconductor on the wafer surface have a maximum shortest dimension. The combined percentage of semiconductor in the total wafer surface area and the maximum shortest dimensions of each semiconductor region are small enough so that the wafer surface is hydrophilic enough to wet.

### BACKGROUND OF THE INVENTION

This invention relates to wet cleaning of wafer surfaces following chemical mechanical planarization (CMP). More specifically, this invention relates to a wafer structure comprising regions of hydrophobic material such as semiconductor and hydrophilic material such as dielectric that allow the surface of the wafer to be wet cleaned following CMP.

Chemical mechanical planarization (CMP) is a process that causes removal of a portion of a layer deposited during a processing step on a wafer. Residual slurry particles and metals usually become exposed on the surface of the wafer after the CMP step is completed. A previously known cleaning technique removes the residual particles by placing the wafer in a scrubber in which dilute (e.g., about 2%) aqueous ammonium hydroxide (NH₄OH) is administered to the wafer surface while polyvinyl alcohol (PVA) brushes physically remove the residual slurry particles and metals. The surface of the wafer must be hydrophilic (i.e., attracts water) so that the wafer easily wets when placed in the aqueous environment within the scrubbing tool. When the wafer successfully wets, the PVA brushes can come into intimate contact with residual particles on the wafer surface and effect their removal.

This aqueous cleaning technique has been used to remove residual slurry particles from a silicon dioxide dielectric surface following CMP and to remove residual slurry particles from a combined silicon dioxide and silicon nitride dielectric surface following shallow trench isolation (STI) planarization. Both silicon dioxide and silicon nitride are hydrophilic. However, when silicon is exposed following a CMP process, a hydrophobic (i.e., water-repelling) surface is created, which makes it difficult to use aqueous NH₄OH-based scrubbing. The silicon surface does not sufficiently wet to permit the PVA brushes from coming into intimate contact with the wafer surface, and the residual slurry particles and/or metal contaminants are not removed.

One previously known method for transforming a silicon surface into a hydrophilic state involves immersing the exposed silicon surface in a “SC1” wet clean comprising NH₄OH, hydrogen peroxide (H₂O₂), and deionized water. Then an “SC2” wet clean containing hydrochloric acid (HCl), H₂O₂, and deionized water is performed. The silicon wafer surface oxidizes and becomes hydrophilic so that it can be successfully cleaned by NH₄OH scrubbing. However, the disadvantages of this process include significant extra chemical consumption and the requirement of a separate wet bench, which may require significant additional cost.

Alternatively, the chemical delivery system of the scrubber is reconfigured by delivering an “SC1” solution to a first PVA brush station, and an “SC2” solution to a second PVA brush station in order to transform the silicon surface into a hydrophilic state. This avoids the need for a separate wet bench arrangement, but requires a significant amount of equipment re-engineering to the scrubber chemical delivery system which is typically undesirable and may also add significant cost. A further disadvantage of using an “SC1” wet clean is that it often introduces metal contamination onto the silicon surface (e.g., Fe, Cu, etc.) as a result of using impure hydrogen peroxide. The metal contaminants may not be completely removed by the “SC2” wet clean.

It would therefore be desirable to provide a method and apparatus for forming a wafer surface comprising semiconductor that is hydrophilic after a CMP process.

It would also be desirable to provide a wafer surface comprising semiconductor and dielectric that attracts enough water to allow the wafer surface to wet so that residual slurry particles and metal contaminants may be removed therefrom.

### SUMMARY OF THE INVENTION

It is therefore an object of the present invention to provide a method and apparatus for forming a wafer surface comprising semiconductor that is hydrophilic after a CMP process.

It is also an object of the present invention to provide a wafer surface comprising semiconductor and dielectric that attracts enough water to allow the wafer surface to wet so that residual slurry particles and metal contaminants may be removed therefrom.

Wafers of the present invention comprise a surface of hydrophobic material such as semiconductor and hydrophilic material such as dielectric formed in such a way that allows the wafer surface to wet so that residual particles (i.e., residual slurry particles and metal contaminants) can be removed therefrom during a wet clean. Regions of hydrophobic material and hydrophilic material are exposed after a CMP removal process. The percentage of the total wafer surface area that comprises hydrophobic material after CMP is less than or equal to a predetermined fraction, and the remainder of the wafer surface area comprises hydrophilic material. Also, each of the regions of hydrophobic material on the wafer surface have a maximum shortest dimension.

The combined percentage of hydrophobic material in the total wafer surface area and the maximum shortest dimension of the regions of hydrophobic material are small enough so that the wafer surface as a whole is hydrophilic enough to wet. Hydrophilic wafer surfaces of the present invention can be wet cleaned, for example, with a standard scrubber using aqueous ammonium hydroxide (NH₄OH). Wafer surfaces of the present invention may, for example, comprise elongated strips of dielectric and semiconductor, localized regions of semiconductor immersed in a sea of dielectric, or interspersed regions of dielectric and silicon.

### BRIEF DESCRIPTION OF THE DRAWINGS

The above-mentioned objects and features of the present invention can be more clearly understood from the following detailed description considered in conjunction with the following drawings, in which the same reference numerals denote the same structural elements throughout, and in which:

FIGS. 1A-1B are, respectively, cross sectional and top views of a wafer comprising regions of semiconductor and dielectric in accordance with the principles of the present invention;

FIGS. 2A-2G are cross section views of process steps for forming a wafer comprising regions of semiconductor and dielectric in accordance with the principles of the present invention;

FIG. 3 is a top view of another wafer comprising regions of semiconductor and dielectric in accordance with the principles of the present invention;

FIG. 4 is a top view of another wafer comprising regions of semiconductor and dielectric in accordance with the principles of the present invention; and

FIG. 5 is a top view of another wafer comprising regions of semiconductor and dielectric in accordance with the principles of the present invention.

### DETAILED DESCRIPTION OF THE PREFERRED EMBODIMENT

A wafer of the present invention comprises regions of hydrophobic material such as semiconductor and hydrophilic material such as dielectric that are exposed at the surface of the wafer. The percentage of the total surface area of the wafer that is hydrophobic material is less than or equal to a first fraction (e.g., %60), and the remaining surface area of the wafer comprises hydrophilic material (e.g., 40%). The shortest dimension of each region of hydrophobic material is less than or equal to a first width (e.g., 500 μm), so that the regions of hydrophobic material are not too large. The first fraction and the first width limit the size as well as the density of the regions of hydrophobic material to prevent the wafer surface as a whole from becoming hydrophobic. The first fraction and the first width ensure that there is enough hydrophilic material at the wafer surface among the regions of hydrophobic material so that the attractive forces inherent in the hydrophilic material counteract the repulsive forces inherent in the hydrophobic material. Hydrophobicity can be measured by contact angle measurements. A surface is considered hydrophilic when the contact angle measurements following CMP are most preferably less than 5 degrees, preferably less than 10 degrees, but acceptable if less than 15 degrees.

Wafer surfaces of the present invention wet sufficiently so that residual particles (i.e., residual slurry particles and metal contaminants) can be removed therefrom in a wet clean process. For example, wafer surfaces of the present invention may be wet cleaned in a standard scrubber using aqueous ammonium hydroxide (NH₄OH). The present invention eliminates the extra cost, steps, and equipment that are needed to treat the wafer surface so that the semiconductor becomes hydrophilic.

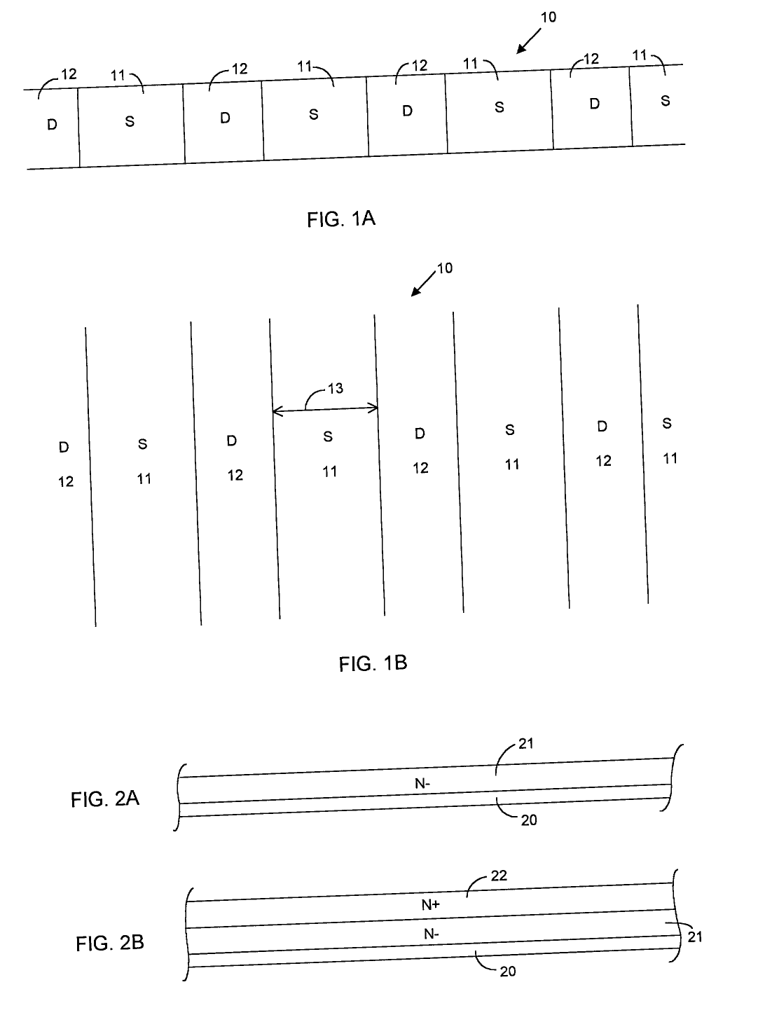

Wafer 10 is formed in accordance with the principles of the present invention. A cross section of wafer 10 is shown in FIG. 1A, and a top view of wafer 10 is shown in FIG. 1B. Wafer 10 contains alternating elongated strips 11 of semiconductor (i.e., hydrophobic material) and strips 12 of dielectric (i.e., hydrophilic material). Wafer 10 may be formed by depositing a semiconductor layer (e.g., silicon, Gallium Arsenide (GaAs), or Germanium (GE)) on a substrate, and then masking and selectively etching the semiconductor layer to form elongated strips 11. A blanket layer of dielectric (e.g., SiO₂, SiOₓ, Borophosphosilicate glass (BPSG), phosphosilicate glass (PSG), or a low-k dielectric such as fluorosilicate glass (FSG)) may then be deposited on top of strips 11. Chemical mechanical planarization (CMP) may then be performed to remove excess dielectric to expose semiconductor regions 11 and to form dielectric regions 12.

After the CMP removal step, residual particles including slurry particles and metal contaminants may remain on the surface of wafer 10. The residual slurry particles and metal contaminants may be removed during a wet cleaning step. For example, the wafer may be placed in a scrubber in which dilute (e.g., about 2%) aqueous ammonium hydroxide (NH₄OH) is administered to the wafer surface while polyvinyl alcohol (PVA) brushes physically remove the residual slurry particles and metal contaminants. The combined surface area of semiconductor strips 11 in wafer 10 is less than or equal to a first fraction of the total surface area of wafer 10, and the remaining surface area of the wafer is dielectric. The first fraction is most preferably %50, preferably %60, but may be 70%. In the example shown in FIGS. 1A-1B, semiconductor is about 57% of the surface area of wafer 10 and dielectric is about 43%.

In addition, the shortest surface dimension of each semiconductor strip in wafer 10 is less than or equal to a first width. For example, with respect to a semiconductor strip 11, the shortest surface dimension is width 13 shown in FIG 1B. The first width is most preferably between 0.25-500 μm, preferably less than 2.5 mm, but may be a large as 5 mm. The semiconductor strips may have longer surface dimensions that are greater than the first width and still provide a sufficiently hydrophilic wafer surface, as long as the shortest surface dimension is less than or equal to the first width. For example, the semiconductor strips may have a length (up and down in FIG. 1B) that is much greater than the first width. A maximum shortest surface dimension is required for each of the semiconductor regions on the wafer surface so that the hydrophobic forces of a semiconductor region do not prevent residual particles from being removed from that region during a post-CMP wet clean.

By making the semiconductor strips of wafer 10 less than or equal to a first fraction and less than or equal to a first width, the hydrophilic state of the dielectric counterbalances the hydrophobic state of the semiconductor so that the surface of wafer 10 attracts enough water to wet during a wet clean. Wafer 10 wets completely during a wet clean so that the PVA brushes in a scrubber can come into intimate contact with the wafer surface to remove the residual slurry particles and metal contaminants therefrom. The wafer is cleaned such that metallic contamination is most preferably less than 5×10⁹ atoms/cm², preferably less than 1×10¹⁰ atoms/cm², and acceptable if less than 5×10¹⁰ atoms/cm². And the wafer is cleaned such that residual slurry particle density, adhered to the wafer surface, is most preferably reduced to less than 0.03/cm², preferably reduced to less than 0.06/cm², and acceptable if reduced to less than 0.15/cm².

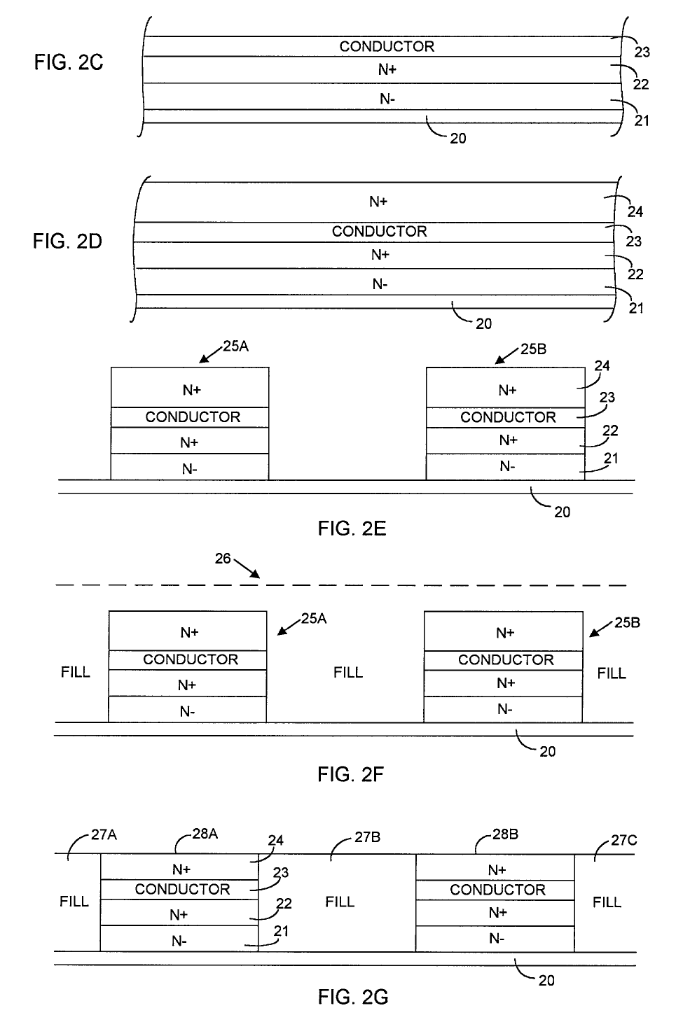

In one embodiment of the present invention, the semiconductor and dielectric strips of FIGS. 1A-1B may be formed according to the process flow steps illustrated in FIGS. 2A-2G. FIGS. 2A-2G illustrate cross sectional views of process steps for forming elongated strips, which extend into and out of the page. Alternatively, the semiconductor and dielectric regions of FIGS. 1A-1B and other embodiments of the present invention may be formed using other process steps.

First, an antifuse layer 20 is deposited as shown in FIG. 2A. This typically is a 25-200 Å (angstroms) thick layer of silicon dioxide which can be deposited with any one of very well-known processes. Subsequently, silicon layer 21 is deposited (e.g., typically 1000-4000 Å thick) using a CVD (chemical vapor deposition) process where an n-type phosphorous dopant is deposited along with the deposition of, for instance, the polysilicon semiconductor material or where the n-type dopant is ion implanted following the deposition of the layer. This layer is, for example, doped to a level of 5×10¹⁶-10¹⁸/cm³.

Now, as shown in FIG. 2B a highly doped n+ layer 22 is deposited again using CVD. This layer may be approximately 300-3000 Å thick and in one embodiment is doped to a level of >10¹⁹/cm³. Adjacent silicon layers 21 and 22 are shown with different concentrations of n-type doping. These layers may be formed with one deposition followed by an ion implantation step at two different energy and/or dosage levels to obtain the two doping levels.

A conductive layer 23 which may be 500-1500 Å thick is formed using any one of numerous well-known thin film deposition processes such as sputtering as shown in FIG. 2C. A refractory metal may be used or a silicide of a refractory metal. Also, aluminum or copper can be used, or, more simply, the heavily doped silicon can be the conductor.

Next, another semiconductor layer of, for instance, highly doped n+ polysilicon approximately 1500-2000 Å thick doped to a level of >10¹⁹/cm³ is formed on top of layer 23. This is shown as layer 24 in FIG. 2D. Following a subsequent CMP removal step, the thickness of layer 24 is typically reduced to between 300 Å and 2000 Å thick.

A masking and etching step is now used to define elongated strips of semiconductor regions, such as regions 25A and 25B shown in FIG. 2E. An ordinary masking and etching step for instance using plasma etching, may be used. Etchants can be used that stop on antifuse layer 20, thus preventing this layer from being etched away. Thus, layer 20 can be considered an etchant stop layer depending on the specific etchants used.

Now as shown in FIG. 2F, the spaces between the semiconductor regions 25A and 25B are filled with a dielectric layer 26 (e.g., SiO₂), which may be formed with a high density plasma chemical vapor deposition (HDP-CVD) process. The dotted line in FIG. 2F indicates that dielectric layer 26 is filled to any suitable height, including above the upper edge of semiconductor regions 25A and 25B. Preferably, dielectric layer 26 is filled up to and no higher than the upper edge of the semiconductor regions to minimize the amount of subsequent planarization needed. This tends to minimize non-uniformities across the entire wafer. Further details of this technique are discussed in commonly-assigned U.S. patent application Ser. No. ______ to Vyvoda et al., filed concurrently herewith, (Attorney Docket No. MS-2), which is hereby incorporated by reference herein in its entirety.

A CMP step is subsequently performed to planarize the upper surface of the wafer shown in FIG. 2F in one embodiment. This planarization can reduce the thickness of layer 24 to approximately 300 Å. Thus, this layer may end up being approximately the same thickness as layer 22. The removal step is performed so that any dielectric material above the semiconductor regions (such as 25A and 25B) is removed to expose the upper surfaces of these strips (such as surfaces 28A-28B) as shown in FIG. 2G. The dielectric is planarized down to the same height as the semiconductor strips to form dielectric strips, such as strips 27A-27C. The dielectric strips are located in between the semiconductor strips.

The surface of the wafer of FIG. 2G comprises alternating strips of semiconductor and dielectric. The combined surface area of the semiconductor (e.g., 50% in FIG. 2G) is less than or equal to a first fraction, and the shortest dimension of each semiconductor strip is less than or equal to a first width, as discussed above with respect to FIGS. 1A-1B. Therefore, the surface of the wafer wets during a wet clean allowing residual slurry particles and metal contaminants remaining after the CMP step to be removed therefrom.

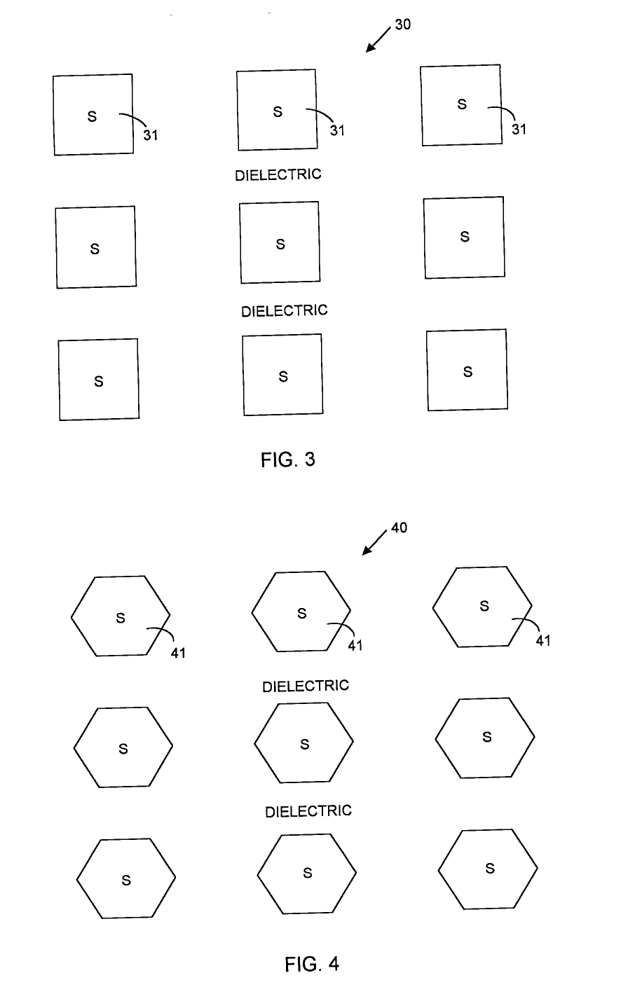

Further embodiments of the present invention are shown in FIGS. 3 and 4. FIGS. 3 and 4 are views from the top looking down on the surface of wafers 30 and 40, respectively. The surface of wafer 30 comprises a plurality of square shaped regions 31 of semiconductor (e.g., silicon) interspersed within a sea of dielectric material (e.g., SiO₂). The surface of wafer 40 comprises a plurality of hexagonally shaped regions 41 of semiconductor (e.g., silicon) interspersed within a sea of dielectric material (e.g., SiO₂). The semiconductor and dielectric regions may be formed using any suitable processing techniques. For example, the semiconductor and dielectric regions may be formed using process steps such as the ones shown in FIGS. 2A-2G, but modifying the masking and etching step of FIG. 2E to form square or hexagonal semiconductor regions.

As long as the combined surface area of the semiconductor regions is less than or equal to a first fraction, and the shortest dimension of each of the semiconductor regions 31/41 is less than or equal to a first width, residual slurry particles and metal contaminants can be removed from the wafer surface during a standard wet cleaning process. The examples discussed above with respect to the first fraction and the first width in FIGS. 1A-1B also apply to the embodiment of FIGS. 3 and 4. The embodiments of FIGS. 3-4 illustrate wafers in which the combined semiconductor surface area is less than 50% of the total wafer surface area. However, the present invention includes structures in which the combined semiconductor surface area is greater than 50% of the total wafer surface area, as long as it is less than or equal to the first fraction.

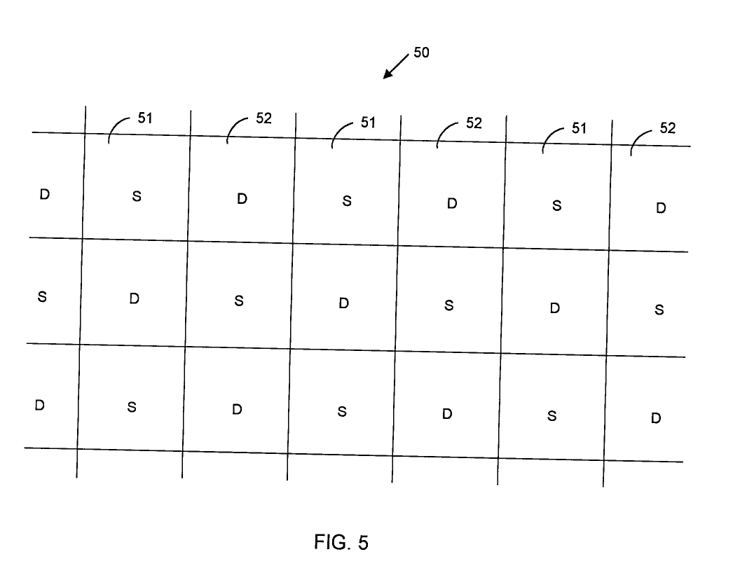

Another embodiment of the present invention is shown in FIG. 5. FIG. 5 is a view from the top looking down on the surface of wafer 50. Wafer 50 comprises alternating square regions 51 of semiconductor and regions 52 of dielectric. Regions 51 and 52 may be formed using any suitable process steps, such as the process steps discussed above with respect to FIGS. 2A-2G, by modifying the masking and etching step of FIG. 2E to form square semiconductor regions as shown in FIG. 5. As long as the combined surface area of the semiconductor regions is less than or equal to a first fraction and the shortest dimension of each of the semiconductor regions 51 is less than or equal to a first width, residual slurry particles and metal contamiants can be removed from the wafer surface during a standard wet cleaning process. The examples used above with respect to the first fraction and the first width in FIGS. 1A-1B also apply to the embodiment of FIG. 5.

If desired, any of the wafers of the present invention may be formed by first depositing, selectively masking and etching a dielectric (e.g., SiO₂) layer to form dielectric regions, and subsequently depositing a semiconductor (e.g., silicon) layer on top of the dielectric regions. CMP may then be performed to remove excess semiconductor and to expose the surface of the dielectric regions. The resulting wafer structure has a surface comprising a combined semiconductor surface area that is less than or equal to a first fraction, and the shortest dimension of each of the semiconductor regions on the wafer is less than or equal to a first width, as discussed above with respect to the previous embodiments.

Persons skilled in the art further will recognize that the present invention may be implemented using structures and process steps other than those shown and discussed above. All such modifications are within the scope of the present invention, which is limited only by the claims which follow.

What is claimed is:

1. A wafer having a surface, the wafer comprising:
a plurality of regions of semiconductor and dielectric exposed at the surface of the wafer after chemical mechanical planarization, wherein the semiconductor regions have a total surface area that is less than or equal to a first fraction of a total surface area of the wafer and each of the semiconductor regions have a shortest surface dimension that is less than or equal to a first width, the first fraction and the first width ensuring that the surface of the wafer can attract enough water to wet sufficiently allowing removal of residual particles therefrom.

2. The wafer of claim 1 wherein the first fraction equals 60%.

3. The wafer of claim 1 wherein the first fraction equals 50%.

4. The wafer of claim 1 wherein the first width equals 2.5 millimeters.

5. The wafer of claim 1 wherein the first width equals 500 microns.

6. The wafer of claim 1 wherein the semiconductor regions comprise silicon.

7. The wafer of claim 1 wherein the dielectric regions comprise silicon dioxide.

8. The wafer of claim 1 wherein the regions of dielectric and semiconductor alternate along the surface of the wafer.

9. The wafer of claim 1 wherein the regions of dielectric are elongated strips.

10. The wafer of claim 1 wherein the regions of semiconductor are elongated strips.

11. The wafer of claim 1 wherein the regions of dielectric are rectangular.

12. The wafer of claim 1 wherein the regions of semiconductor are rectangular.

13. The wafer of claim 1 wherein the regions of semiconductor are hexagonal.

14. The wafer of claim 1 wherein the regions of semiconductor are interspersed within a sea of dielectric.

15. A method for cleaning a surface of a wafer, comprising:
depositing a semiconductor layer and a dielectric layer;
removing portions of the semiconductor layer or the dielectric layer using chemical mechanical planarization to expose surfaces of dielectric and semiconductor regions, wherein the semiconductor regions have a combined surface area that is less than or equal to a first fraction of a surface area of the wafer and each of the semiconductor regions has a shortest surface dimension that is less than or equal to a first width; and
cleaning the wafer surface using a wet clean technique to remove residual particles therefrom.

16. The method of claim 15 wherein the first fraction equals 60%.

17. The method of claim 15 wherein the first fraction equals 50%.

18. The method of claim 15 wherein the first width equals 2.5 millimeters.

19. The method of claim 15 wherein the first width equals 500 microns.

20. The method of claim 15 wherein the semiconductor regions comprise silicon.

21. The method of claim 15 wherein the dielectric regions comprise silicon dioxide.

22. The method of claim 15 wherein the regions of dielectric and semiconductor alternate along the surface of the wafer.

23. The method of claim 15 wherein the regions of dielectric are elongated strips.

24. The method of claim 15 wherein the regions of semiconductor are elongated strips.

25. The method of claim 15 wherein the regions of dielectric are rectangular.

26. The method of claim 15 wherein the regions of semiconductor are rectangular.

27. The method of claim 15 wherein the regions of semiconductor are hexagonal.

28. The method of claim 15 wherein depositing the semiconductor layer and the dielectric layer comprises first depositing the semiconductor layer, selectively masking and etching the semiconductor layer, and subsequently depositing the dielectric layer over the semiconductor layer.

29. The method of claim 15 wherein the regions of semiconductor are interspersed within a sea of dielectric.

30. A wafer having a surface, the wafer comprising:
means for attracting water to the surface of the wafer; and
means for repelling water from the surface of the wafer comprising regions that have a combined surface area that is less than or equal to a first fraction of a surface area of the wafer,
wherein each of the regions has a shortest surface dimension that is less than or equal to a first width, and the first fraction and the first width ensure that the surface of the wafer can attract enough water to wet sufficiently allowing removal of residual particles therefrom.

31. The wafer of claim 30 wherein the first fraction equals 60%.

32. The wafer of claim 30 wherein the first fraction equals 50%.

33. The wafer of claim 30 wherein the first width equals 2.5 millimeters.

34. The wafer of claim 30 wherein the first width equals 500 microns.

35. The wafer of claim 30 wherein the means for repelling water comprises silicon.

36. The wafer of claim 30 wherein the means for attracting water comprises silicon dioxide.

37. The wafer of claim 30 wherein the means for attracting water comprises elongated strips of dielectric.

38. The wafer of claim 30 wherein the means for attracting water comprises of rectangular regions of dielectric.

39. The wafer of claim 30 wherein the means for attracting water comprises dielectric regions, the means for repelling water comprises semiconductor regions, and wherein the dielectric regions and semiconductor regions alternate along the surface of the wafer.

40. The wafer of claim 30 wherein the means for repelling water comprises elongated strips of semiconductor.

41. The wafer of claim 30 wherein the means for repelling water comprises rectangular regions of semiconductor.

42. The wafer of claim 30 wherein the means for repelling water comprises hexagonal regions of semiconductor.

43. The wafer of claim 30 wherein the means for attracting water comprises dielectric, the means for repelling water comprises semiconductor regions, and the semiconductor regions are interspersed within a sea of dielectric.

44. A wafer having a surface, the wafer comprising:
a plurality of regions of hydrophobic material and hydrophilic material exposed at the surface of the wafer after chemical mechanical planarization, wherein the regions of hydrophobic material have a total surface area that is less than or equal to a first fraction of a total surface area of the wafer and each of the regions of hydrophobic material have a shortest surface dimension that is less than or equal to a first width, the first fraction and the first width ensuring that the surface of the wafer can attract enough water to wet sufficiently allowing removal of residual particles therefrom.

45. The wafer of claim 44 wherein the first fraction equals 60%.

46. The wafer of claim 44 wherein the first fraction equals 50%.

47. The wafer of claim 44 wherein the first width equals 2.5 millimeters.

48. The wafer of claim 44 wherein the first width equals 500 microns.

49. The wafer of claim 44 wherein the hydrophobic material comprises silicon.

50. The wafer of claim 44 wherein the hydrophilic material comprises silicon dioxide.

51. The wafer of claim 44 wherein the regions of hydrophobic material and hydrophilic material alternate along the surface of the wafer.

52. The wafer of claim 44 wherein the regions of hydrophilic material and hydrophobic material are elongated strips.

53. The wafer of claim 44 wherein the regions of hydrophilic material are rectangular.

54. The wafer of claim 44 wherein the regions of hydrophobic material are rectangular.

55. The wafer of claim 44 wherein the regions of hydrophobic material are hexagonal.

56. The wafer of claim 44 wherein the regions of hydrophobic material are interspersed within a sea of hydrophilic material.
